(19) United States
(12) Patent Application Publication
(10) Pub. No.: US 2026/0179566 A1
(43) Pub. Date: Jun. 25, 2026

(54) LIGHT EMITTING DISPLAY APPARATUS

(71) Applicant: LG Display Co., Ltd., Seoul (KR)

(72) Inventors: Min-Woo PARK, Paju-si (KR); Jun-Ho BONG, Paju-si (KR)

(73) Assignee: LG Display Co., Ltd., Seoul (KR)

(21) Appl. No.: 19/395,897

(22) Filed: Nov. 20, 2025

(30) Foreign Application Priority Data
Dec. 24, 2024 (KR) 10-2024-0195685

(51) Int. Cl. G09G 3/3266

(52) U.S. Cl. CPC G09G 3/3266; G09G 2300/0426; G09G 2310/0286; G09G 2310/08

(57) ABSTRACT

A light emitting display apparatus includes a scan driving circuit including a scan stage having a first buffer portion outputting a first scan signal, and a second-first, and second-second buffer portions outputting two second scan signals. The first buffer portion includes first and second buffer transistors commonly connected to a BG node. The second-first buffer portion includes a third buffer transistor connected to an SQ node, and a fourth buffer transistor connected to the BG node. The second-second buffer portion includes a fifth buffer transistor connected to the SQ node, and a sixth buffer transistor connected to the BG node. The first buffer transistor receives a gate high voltage, the second, fourth, and sixth buffer transistors receive a gate low voltage, and the third and fifth buffer transistors receive a second-first scan clock and a second-second scan clock, respectively.

### CROSS REFERENCE TO RELATED APPLICATIONS

This application claims the benefit of and priority to Korean Patent Application No. 10-2024-0195685 filed in Republic of Korea on Dec. 24, 2024, the entire contents of which are incorporated herein by reference for all purposes.

### BACKGROUND

### 1. Technical Field

The present disclosure relates to a light emitting display apparatus.

### 2. Discussion of Related Art

As the information society develops, a demand for display apparatuses for displaying images have increased in various forms, and in recent years, various flat display apparatuses such as organic light emitting display apparatuses and liquid crystal display apparatuses have been used.

A gate driving circuit of a light emitting display apparatus includes a scan driving circuit that generates a scan signal. A buffer transistor in a stage of the scan driving circuit that outputs the scan signal has a width greater than a vertical length of the stage.

Accordingly, the buffer transistor is arranged in a horizontal direction, so that a width of a non-display region of a display panel where the scan driving circuit is located increases.

Therefore, a bezel of the light emitting display apparatus increases, making it difficult to achieve a narrow bezel.

The description of related art should not be considered prior art merely because it is mentioned in or associated with this section. The description of related art includes information that describes one or more aspects of the subject technology, and the description in this section does not limit the scope of the present disclosure.

### SUMMARY

In one or more aspects, an advantage of the present disclosure is to provide a light emitting display apparatus that can implement a narrow bezel by changing design of a scan driving circuit such that a buffer transistor is arranged in a vertical direction.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, in one or more aspects, a light emitting display apparatus includes a display panel including a display region and a non-display region, the display region including pixels, a light emitting diode and a plurality of transistors electrically connected to the light emitting diode, in the pixel, and a scan driving circuit located in the non-display region and including a scan stage which includes a first buffer portion that outputs a first scan signal commonly applied to the pixels of two adjacent horizontal lines, and a second-first buffer portion and a second-second buffer portion that output two second scan signals applied to the pixels of the two adjacent horizontal lines, respectively, wherein the first buffer portion includes a first buffer transistor and a second buffer transistor whose gate electrodes are commonly connected to a BG node, wherein the second-first buffer portion includes a fourth buffer transistor whose gate electrode is connected to the BG node, and a third buffer transistor whose gate electrode is connected to an SQ node that receives a voltage of an output terminal of the first buffer portion, wherein the second-second buffer portion includes a sixth buffer transistor whose gate electrode is connected to the BG node, and a fifth buffer transistor whose gate electrode is connected to the SQ node, wherein the first buffer transistor receives a gate high voltage, wherein the second, fourth, and sixth buffer transistors receive a gate low voltage, and wherein the third and fifth buffer transistors receive a second-first scan clock and a second-second scan clock, respectively.

In one or more aspects, a light emitting display apparatus includes a display panel including a display region and a non-display region, the display region including pixels, a light emitting diode and a plurality of transistors electrically connected to the light emitting diode, in the pixel, and a plurality of scan stages in the non-display region, each of the plurality of scan stages including a first buffer portion that outputs a first scan signal commonly applied to the pixels of two adjacent horizontal lines, and a second-first buffer portion and a second-second buffer portion that output two second scan signals applied to the pixels of the two adjacent horizontal lines, respectively, wherein the plurality of scan stages include n-th and n+1-th scan stages which correspond to 2n−1-th to 2n+2-th horizontal lines of the display region, and are respectively disposed on one side and the other side of the display region, wherein the n-th scan stage outputs an n-th first scan signal and 2n−1-th and 2n-th second scan signals for driving the 2n−1-th and 2n-th horizontal lines, and wherein the n+1-th scan stage outputs an n+1-th first scan signal and 2n+1-th and 2n+2-th second scan signals for driving the 2n+1-th and 2n+2-th horizontal lines.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing general description and the following detailed description are examples and explanatory and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a view schematically illustrating a light emitting display apparatus according to an embodiment of the present disclosure;

FIG. 2 is a circuit diagram schematically illustrating an example of a pixel according to an embodiment of the present disclosure;

FIG. 3 is a view illustrating a configuration of a gate driving portion of a light emitting display apparatus according to an embodiment of the present disclosure;

FIG. 4 is a view schematically illustrating a structure of a scan stage of a scan driving circuit according to an embodiment of the present disclosure;

FIG. 5 is a waveform view schematically illustrating timings of signals driving a scan stage according to an embodiment of the present disclosure;

FIG. 6 is a view comparing non-display regions of display panels according to a comparative example and an embodiment of the present disclosure; and

FIG. 7 is a cross-sectional view schematically illustrating an example of a cross-sectional structure of a display panel according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, nodes, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. Any references to singular may include plural, and vice versa, unless expressly stated otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, nodes, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” “first-second,” “second-first,” “second-second,” “first B,” “A,” “B,” “(a),” “(b),” node-identifying terms (e.g., BG, SQ, QB, CNT, NO1, NO2_1, and NO2_2), transistor-identifying terms (e.g., TA, T1b, T2b, Tb3, Tb4, Tb5, Tb6, Ts1, Ts2, Ts3 and Ts4), and the like may be used herein to describe various elements (e.g., layers, films, components, electrodes, structures, nodes, transistors, sections, members, parts, regions, areas, portions, steps, operations, and/or the like), these elements should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” “horizontal direction,” “vertical direction,” “width direction,” “widthwise direction,” “length direction,” “lengthwise direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements. Moreover, “at least some,” “some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise. In one or more aspects, unless stated otherwise, the term “n-th” may refer to “nnd” (e.g., 2nd where n is 2), or “nrd” (e.g., 3rd where n is 3), and n may be a natural number or a whole number.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein. For example, the term “part” or “unit” may apply to, for example, a circuit, a component, an integrated circuit, a computational block of a circuit device, or a structure configured to perform a described function as should be understood by one of ordinary skill in the art.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

In description of flow of a signal, for example, when a signal is provided (e.g., transferred or transmitted) from a node A to a node B, this may include a case where the signal is provided from the node A to the node B via one or more nodes unless a phrase such as “immediately provided,” “directly provided” or the like is used.

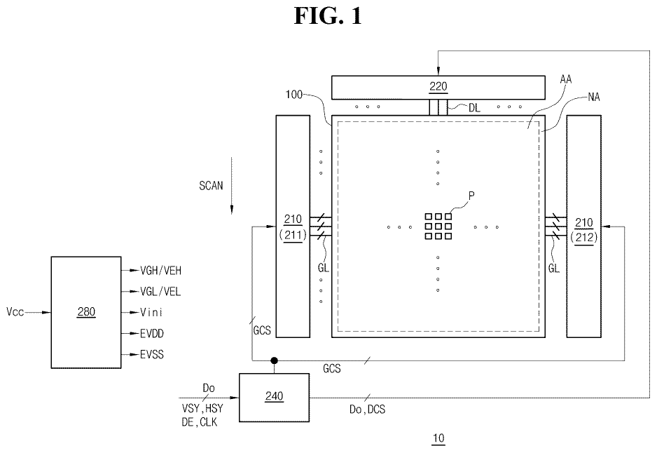

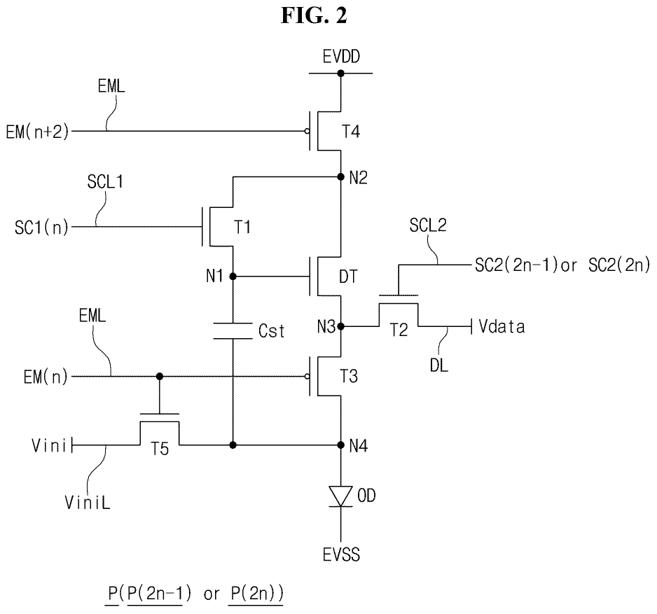

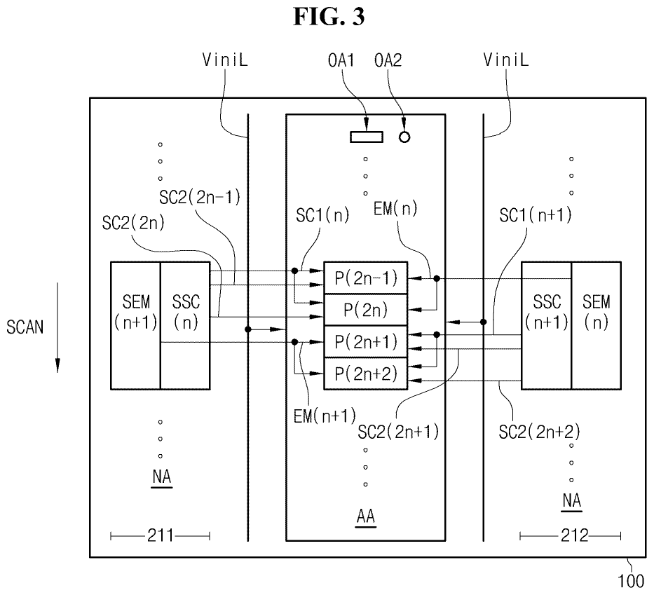

FIG. 1 is a view schematically illustrating a light emitting display apparatus according to an embodiment of the present disclosure. FIG. 2 is a circuit diagram schematically illustrating an example of a pixel according to an embodiment of the present disclosure. FIG. 3 is a view illustrating a configuration of a gate driving portion of a light emitting display apparatus according to an embodiment of the present disclosure.

Prior to a specific description, an organic light emitting display apparatus is described as an example of the light emitting display apparatus 10.

Referring to FIGS. 1 to 3, the light emitting display apparatus 10 of this embodiment can include a display panel 100 and a driving circuit portion that drives the display panel 100.

Here, the driving circuit portion can include, for example, a gate driving portion (or gate driving circuit) 210, a data driving portion (or data driving circuit) 220, and a timing control portion (or timing control circuit) 240. In addition, the driving circuit portion can include a power supply portion (or power supply circuit) 280 that supplies power required for driving the display panel 100, the gate driving portion 210, the data driving portion 220, and the timing control portion 240.

The display panel 100 can include a display region AA that displays an image, and a non-display region NA arranged outside the display region AA (or surrounding the display region AA).

In the display region AA, a plurality of pixels P can be arranged in a matrix form along a plurality of horizontal lines (or row lines) and a plurality of vertical lines (or column lines).

Here, the plurality of pixels P can include pixels that display different colors, for example, red, green, and blue pixels that display red, green, and blue, respectively, but not limited thereto.

In the display panel 100, various signal lines that transmit driving signals for driving the pixels P can be formed on a substrate.

In this regard, for example, a plurality of data lines DL that transmit data signals (or data voltages) which are image signals can extend in the vertical direction and be connected to the pixels P of the respective vertical lines.

In addition, a gate line GL that transmits a gate signal (or gate voltage) can extend in the horizontal direction and be connected to the pixel P of the corresponding horizontal line.

In this embodiment, a plurality of gate signals can be used to drive each pixel P, for example, a first scan signal SC1, a second scan signal SC2, and an emission control signal EM can be used. Accordingly, a plurality of gate lines GL respectively transmitting the plurality of gate signals can be used, for example, a first scan line SCL1, a second scan line SCL2, and an emission control line EML can be used.

As such, the plurality of pixels P can be defined by the plurality of data lines DL and gate lines GL intersecting each other.

Each pixel P can include a light emitting diode OD as a light emitting element, and a plurality of transistors and at least one capacitor for driving the light emitting diode OD.

Meanwhile, in this embodiment, for convenience of explanation, an 6T1C structure in which the pixel P is equipped with six transistors T1 to T5 and DT and one capacitor Cst as illustrated in FIG. 2 is taken as an example.

Referring to FIG. 2, the pixel P can include a plurality of switching transistors, for example, first transistor T1 to fifth transistor T5, a driving transistor DT, a storage capacitor Cst, and the light emitting diode OD.

Each of the first to fifth transistors T1 to T5 and the driving transistor DT can include a first electrode, a second electrode, and a gate electrode. One of the first electrode and the second electrode can be a source electrode, and the other of the first electrode and the second electrode can be a drain electrode.

Each of the first to fifth transistors T1 to T5 and the driving transistor DT can be a P-type or N-type transistor. Meanwhile, in FIG. 2, an example is given in which the first, second, and fifth transistors T1, T2, and T5, and the driving transistor DT are configured as N-type transistors, and the third and fourth transistors T3 and T4 are configured as a P-type transistor, but not limited thereto.

The first transistor T1 to the fifth transistor T5 and the driving transistor DT can include semiconductors of the same material or can include semiconductors of different materials. In this regard, for example, some of the first transistor T1 to the fifth transistor T5 and the driving transistors DT can have one semiconductor layer among a polycrystalline silicon layer, an oxide semiconductor layer, and an amorphous silicon layer, and another some of the first transistor T1 to the fifth transistor T5 and the driving transistors DT can have another semiconductor layer among a polycrystalline silicon layer, an oxide semiconductor layer, and an amorphous silicon layer.

An oxide semiconductor has excellent off-current characteristics, and a polycrystalline silicon has excellent mobility. In this embodiment, an example is given in which the first, second, and fifth transistors T1, T2, and T5, and the driving transistor DT can have an oxide semiconductor layer, and the third and fourth transistors T3 and T4 can have a polycrystalline silicon layer, but not limited thereto.

Meanwhile, for convenience of explanation, the pixel P of FIG. 2 can be one of pixels P of adjacent odd and even horizontal lines, which are driven according to gate signals output from an n-th stage of the gate driving portion 210, e.g., one of pixels P(2n−1) and P(2n) of a 2n−1-th horizontal line and a 2n-th horizontal line. In one or more aspects, n may be a natural number. In one or more aspects, n may be a whole number.

In this regard, the gate signals provided to the 2n−1-th or 2n-th horizontal line can be, for example, two scan signals, e.g., a first scan signal (SC1: SC1(n)) and a second scan signal (SC2: SC2(2n−1) or SC2(2n)), and two emission control signals (EM: EM(n) and EM(n+2)).

These gate signals can be described in more detail. The pixel P(2n−1) of the 2n−1-th horizontal line can be provided with a n-th first scan signal SC1(n) and a 2n−1-th second scan signal (SC2(2n−1) output from a corresponding n-th scan stage, a n-th emission control signal EM(n) output from a corresponding n-th emission stage, and a n+2-th emission control signal EM(n+2) output from a n+2-th emission stage that is a subsequent emission stage.

In addition, the pixel P(2n) of the 2n-th horizontal line can be provided with the n-th first scan signal SC1(n) and a 2n-th second scan signal SC2(2n) output from the corresponding n-th scan stage, the n-th emission control signal EM(n) output from the corresponding n-th emission stage, and the n+2-th emission control signal EM(n+2) output from the n+2-th emission stage that is a subsequent emission stage.

As such, the first and second scan signals SC1 and SC2 generated from one scan stage in the gate driving portion 210 and the emission control signal EM generated from one emission stage in the gate driving portion 210 can be applied to two adjacent horizontal lines (e.g., odd and even horizontal lines). The scan stage and the emission stage of the gate driving portion 210 can be described in more detail below.

In this case, in the display region AA, first and second scan lines SCL1 and SCL2, and an emission control line EML that transmit the first and second scan signal SC1 and SC2, and the emission control signal EM to the pixel P can be arranged.

The first transistor T1 can function as a sampling transistor, the second transistor T2 can function as a data supply transistor, the third and fourth transistors T3 and T4 can function as emission control transistors, and the fifth transistor T5 can function as an initialization transistor.

The light emitting diode OD can include an anode electrode and a cathode electrode. The anode electrode of the light emitting diode OD can be connected to a fourth node N4, and the cathode electrode of the light emitting diode OD can be applied with a low-potential driving voltage EVSS.

The driving transistor DT can include, for example, a first electrode connected to a third node N2, a second electrode connected to a second node N2, and a gate electrode connected to a first node N1. The driving transistor DT can provide a driving current to the light emitting diode OD based on a voltage of the first node N1 (e.g., a voltage stored in the storage capacitor Cst).

The first transistor T1 can include a first electrode connected to the first node N1, a second electrode connected to the second node N2, and a gate electrode receiving the first scan signal SC1(n). The first transistor T1 can be turned on in response to the first scan signal SC1(n), so that the driving transistor DT can be in a diode-connection state in which the gate electrode and the drain electrode of the driving transistor DT are electrically short-circuited, and a threshold voltage of the driving transistor DT can be sampled. The sampled threshold voltage of the driving transistor DT can be reflected into the first node N1.

The storage capacitor Cst can be connected between the first node N1 and a fourth node N4. The storage capacitor Cst can store and maintain a voltage applied to the gate electrode of the driving transistor DT. For convenience of explanation, an electrode of the storage capacitor Cst connected to the first node N1 can be referred to as a first electrode, and an electrode of the storage capacitor Cst connected to the fourth node N4 can be referred to as a second electrode.

The second transistor T2 can include a second electrode connected to the data line DL (or receiving the data voltage Vdata), a first electrode connected to the third node N3, and a gate electrode receiving the second scan signal SC2(2n−1) or SC2(n). The second transistor T2 can be turned on in response to the second scan signal SC2(2n−1) or SC2(2n) and can transmit the data voltage Vdata to the third node N3. In this case, the data voltage Vdata applied to the third node N3 can be reflected to the first node N1 in the turn-on state of the first transistor T1, and as a result, the data voltage Vdata can be reflected to the gate electrode of the driving transistor DT.

The third and fourth transistors T3 and T4 can be connected between a line that transmits a high-potential driving voltage EVDD, and the light emitting diode OD, and can form a current path along which the driving current generated by the driving transistor DT flows.

The third transistor T3 can include a first electrode connected to the driving transistor DT at the third node N3, a second electrode connected to the light emitting diode OD at the fourth node N4, and a gate electrode receiving the corresponding n-th emission control signal EM(n).

The fourth transistor T4 can include a first electrode receiving the high-potential driving voltage EVDD, a second electrode connected to the second node N2, and a gate electrode receiving the n+2-th emission control signal EM(n+2).

The third and fourth transistors T3 and T4 can be turned on in response to the corresponding emission control signals EM(n) and EM(n+2). With both the third and fourth transistors T3 and T4 turned on, the driving current can be supplied to the light emitting diode OD, and the light emitting diode OD can emit light at a luminance corresponding to the driving current.

The fifth transistor T5 can include a second electrode connected to an initialization voltage line ViniL that transmits an initialization voltage Vini, a first electrode connected to the fourth node N4, and a gate electrode that receives the corresponding emission control signal EM(n).

The fifth transistor T5 can be turned on in response to the corresponding emission control signal EM(n), and the initialization voltage Vini can be applied to the anode electrode of the light emitting diode OD (e.g., the fourth node N4). Accordingly, the anode electrode of the light emitting diode OD can be initialized (or reset) with the initialization voltage Vini.

The 6T1C structure of the pixel P described above is an example, and the pixel P of this embodiment can be configured with a different structure.

Referring to FIG. 1, the timing control portion 240 can process image data Do input from a host system to be suitable for size, resolution, etc. of the display panel 100 and supply the processed image data Do to the data driving portion 220. The timing control portion 240 can generate a gate control signal GCS and a data control signal DCS using synchronization signals input from the host system, for example, a dot clock signal CLK, a data enable signal DE, a horizontal synchronization signal HSY, and a vertical synchronization signal VSY. By supplying the gate control signal GCS and the data control signal DCS generated in this way to the gate driving portion 210 and the data driving portion 220, respectively, the gate driving portion 210 and the data driving portion 220 can be controlled.

The timing control portion 240 can be configured to be combined with various processors, for example, a microprocessor, a mobile processor, an application processor, etc., depending on a device to be mounted.

Meanwhile, the host system can be, for example, a driving system that drives an electronic device to which the light emitting display apparatus 10 is applied. The electronic device can be, for example, one of a TV (Television), a navigation system, a monitor, a mobile device, and a wearable device.

The gate driving portion 210 can receive the gate control signal GCS from the timing control portion 240, generate the gate signals, and sequentially apply the gate signals to the gate lines GL. For example, the gate signals can be sequentially output from the top to the bottom in the vertical direction.

The gate driving portion 210 can be arranged, for example, on at least one side of the display region AA. In this embodiment, a case is taken as an example in which the gate driving portion 210 is configured to include first and second gate driving portions 211 and 212 arranged on both sides of the display region AA, for example, on the left and right sides of the display region AA.

The gate driving portion 210 can be formed directly in the non-display region NA on the substrate of the display panel 100, for example, in a GIP (gate-in panel) structure. In this case, the gate driving portion 210 can be formed during processes of forming elements of the display panel 100.

The gate driving portion 210 configured with a GIP structure can include, for example, a scan driving circuit that generates the first and second scan signals SC1 and SC2 together and sequentially outputs each of the first and second scan signals SC1 and SC2, and an emission driving circuit that sequentially outputs the emission control signal EM.

Each of the scan driving circuit and the emission driving circuit can be configured with a shift register including a plurality of stages that output the corresponding signals.

The gate driving portion 210 can be described with further reference to FIG. 3. FIG. 3 illustrates a part of the gate driving portion 210, and for convenience of explanation, a configuration of a portion of the gate driving portion 210 that drives four consecutive horizontal lines in the display region AA, for example, the 2n−1-th, 2n-th, 2n+1-th, and 2n+2-th horizontal lines is illustrated.

In the first gate driving portion 211 of the gate driving portion 210, scan stages SSC constituting the scan driving circuit and emission stages SEM constituting the emission driving circuit can be arranged. For example, in the first gate driving portion 211, odd (or even) scan stages (e.g., SSC(n)) among all scan stages SSC constituting the scan driving circuit can be arranged. In addition, in the first gate driving portion 211, even (or odd) emission stages (e.g., SEM(n+1)) among all emission stages constituting the emission driving circuit can be arranged.

In addition, in the second gate driving portion 212 of the gate driving portion 210, scan stages SSC constituting the scan driving circuit and emission stages SEM constituting the emission driving circuit can be arranged. For example, in the second gate driving portion 212, even (or odd) scan stages (e.g., SSC(n+1)) among all scan stages constituting the scan driving circuit can be arranged. In addition, in the second gate driving portion 212, odd (or even) emission stages (e.g., SEM(n)) among all emission stages constituting the emission driving circuit can be arranged.

As described above, a plurality of scan stages SSC constituting the scan driving circuit can be divided and arranged in the first and second gate driving portions 211 and 212 located on the left and right sides. In addition, a plurality of emission stages SEM constituting the emission driving circuit can be divided and arranged in the first and second gate driving portions 211 and 212 located on the left and right sides.

In this embodiment, for convenience of explanation, an example is given in which the odd (e.g., n-th, n+2-th, n+4-th, etc.) scan stages SSC are arranged in the first gate driving portion 211, and the even (e.g., n+1-th, n+3-th, n+5-th, etc.) scan stages SSC are arranged in the second gate driving portion 212. In addition, an example is given in which the even (n+1-th, n+3-th, n+5-th, etc.) emission stages SEM are arranged in the first gate driving portion 211, and the odd (n-th, n+2-th, n+4-th, etc.) emission stages SEM are arranged in the second gate driving portion 212.

The arrangement of the scan stages SSC and the emission stages SEM shown in FIG. 3 is an example, and they can be arranged in a different manner. In this regard, for example, the odd scan stages SSC and the odd emission stages SEM can be arranged in the first gate driving portion 211, and the even scan stages SSC and the even emission stages SEM can be arranged in the second gate driving portion 212.

The scan stage SSC can generate the first scan signal SC1 and output it to the corresponding first scan line SCL1 to provide it to the pixels P of the corresponding odd and even horizontal lines.

For example, the n-th scan stage SSC(n) can generate the n-th first scan signal SC1(n), and the n-th first scan signal SC1(n) can be applied to the pixels P(2n−1) and P(2n) of the corresponding 2n−1-th and 2n-th horizontal lines. In addition, the n+1-th scan stage SSC(n+1) can generate the n+1-th first scan signal SC1(n+1), and the n+1-th first scan signal SC1(n+1) can be applied to the pixels P(2n+1) and P(2n+2) of the corresponding 2n+1-th and 2n+2-th horizontal lines.

Furthermore, the scan stage SSC can sequentially generate two consecutive second scan signals SC2 and output them to the corresponding second scan lines SCL2 to provide them to the pixels P of the corresponding odd and even horizontal lines.

For example, the n-th scan stage SSC(n) can sequentially generate the 2n−1-th second scan signal SC2(2n−1) and the 2n-th second scan signal SC2(2n), and the 2n−1-th and 2n-th second scan signals SC2(2n−1) and SC2(2n) can be applied to the pixels P(2n−1) and P(2n) of the corresponding 2n−1-th and 2n-th horizontal lines, respectively. In addition, the n+1-th scan stage SSC(n+1) can sequentially generate the 2n+1-th second scan signal SC2(2n+1) and the 2n+2-th second scan signal SC2(2n+2), and the 2n+1-th and 2n+2-th second scan signals SC2(2n+1) and SC2(2n+2) can be applied to the pixels P(2n+1) and P(2n+2) of the corresponding 2n+1-th and 2n+2-th horizontal lines, respectively.

The emission stage SEM can generate the emission control signal EM and output it to the corresponding emission control line EML.

For example, the n-th emission stage SEM(n) can generate the n-th emission control signal EM(n), and the n-th emission control signal EM(n) can be applied to the pixels P(2n−1) and P(2n) of the corresponding 2n−1-th and 2n-th horizontal lines. In addition, the n+1-th emission stage SEM(n+1) can generate the n+1-th emission control signal EM(n+1), and the n+1-th emission control signal EM(n+1) can be applied to the pixels P(2n+1) and P(2n+2) of the corresponding 2n+1-th and 2n+2-th horizontal lines.

Moreover, as previously mentioned with reference to FIG. 2, the odd and even pixels P can receive the emission control signal EM output from the emission stage SEM arranged in a subsequent order to the corresponding emission stage SEM.

For example, the n+2-th emission control signal (EM(n+2) in FIG. 2) output from the n+2-th emission stage SEM located in a subsequent order to (or immediately after) the n-th emission stage SEM(n) in the second gate driving portion 212 can be applied to the pixels P(2n−1) and P(2n) of the 2n−1-th and 2n-th horizontal lines. In addition, the n+3-th emission control signal EM output from the n+3-th emission stage SEM located in a subsequent order to (or immediately after) the n+1-th emission stage SEM(n+1) in the first gate driving portion 211 can be applied to the pixels P(2n+1) and P(2n+2) of the 2n+1-th and 2n+2-th horizontal lines.

As described above, in this embodiment, each scan stage SSC can generate the first and second scan signals SC1 and SC2 that drive two horizontal lines of the display region AA, and each emission stage SEM can generate the emission control signal EM that drives two horizontal lines of the display region AA. In addition, the scan stages SSC and the emission stages SEM that sequentially perform scan driving can be distributed and arranged on the left and right sides of the display region AA.

Accordingly, with the four horizontal lines of the display region AA as a unit, one scan stage SSC and one emission stage SEM can be arranged on each side of the display region AA.

According to this arrangement, buffer transistors provided in the scan stage SSC and outputting the scan signals SC1 and SC2 can be arranged in a vertical direction, thereby reducing widths of the non-display regions NA on both sides of the display panel 100. Therefore, a bezel width of the light emitting display apparatus 10 can be reduced, effectively implementing a narrow bezel.

In this regard, the buffer transistors (or their semiconductor layers) that output the scan signals SC1 and SC2 in the scan stage SSC have a large width (e.g., a width in a longitudinal direction), for example, approximately 120 um. Furthermore, a vertical length of the non-display region NA corresponding to each horizontal line of the display region AA is, for example, approximately 80 um.

Accordingly, in a case where the scan stages SSC are provided on both sides of the display region AA in a unit of horizontal line, the vertical length of the scan stage SSC is smaller than the width of the buffer transistor, so that the buffer transistor needs to be arranged in the horizontal direction, which causes the width of the non-display region NA to widen.

However, in this embodiment, the scan stages SSC can be provided on both sides of the display region AA in a unit of four horizontal lines. Accordingly, the vertical length of the scan stage SSC becomes larger than the width of the buffer transistor, thus a width direction of the buffer transistor can be set in the vertical direction, and thus the width of the non-display region NA can be narrowed.

Therefore, the bezel width of the light emitting display apparatus 10 can be reduced, enabling a narrow bezel to be implemented.

Meanwhile, referring to FIG. 3, the initialization voltage line ViniL can be arranged between the gate driving portion 210 and the display region AA.

The initialization voltage line ViniL can supply the initialization voltage Vini from the power supply portion 230 to the pixels P within the display region AA.

In FIG. 3, the initialization voltage line ViniL is illustrated as being located on each of both the left and right sides of the display region AA, but not limited thereto, and the initialization voltage line ViniL can be located on the left or right side.

Furthermore, referring to FIG. 3, one or more optical regions OA1 and OA2 can be disposed in the display region AA.

The one or more optical regions OA1 and OA2 can be arranged to overlap one or more optical electronic devices, for example, a photographing device such as a camera (or image sensor), and/or a detection sensor such as a proximity sensor and an illuminance sensor. For the operation of the optical electronic device, the one or more optical regions OA1 and OA2 can have a light-transmitting structure formed therein and can have transmittance of a certain level or higher. In other words, a number of pixels P per unit area in the one or more optical regions OA1 and OA2 can be smaller than a number of pixels P per unit area in a regular region excluding the optical regions OA1 and OA2 in the display region AA. That is, a resolution of the one or more optical regions OA1 and OA2 can be lower than a resolution of the regular region within the display region AA.

Referring back to FIG. 1, the data driving portion 220 can receive the image data Do and the data control signal DCS from the timing control portion 240, and in response to the data control signal DCS, the data driving portion 220 can convert the image data Do into analog image data, e.g., data voltages Vdata, and outputs them to the respective data lines DL.

The power supply portion 280 can generate DC power required for driving the pixel array and the driving circuit portion of the display panel 100 using, for example, a DC-DC converter. The DC-DC converter can include a charge pump, a regulator, a buck converter, a boost converter, etc.

The power supply portion 280 can receive, for example, a power voltage Vcc that is a driving voltage for driving the light emitting display apparatus 10 from the host system, and generate the DC voltages such as gate low voltages VGL and VEL, gate high voltages VGH and VEH, a high-potential driving voltage EVDD, a low-potential driving voltage EVSS, and an initialization voltage Vini. The gate low voltages VGL and VEL and the gate high voltages VGH and VEH can be supplied to the gate driving portion 210. The high-potential driving voltage EVDD, the low-potential driving voltage EVSS, and the initialization voltage Vini can be supplied in common to the pixels P in the display panel 100.

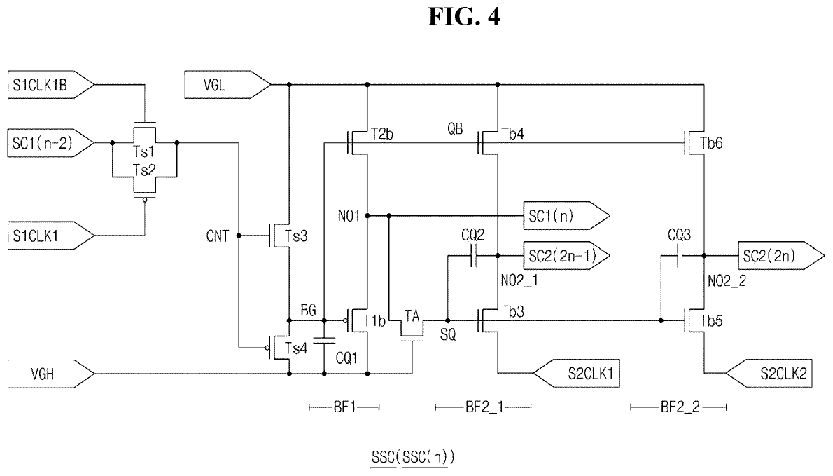

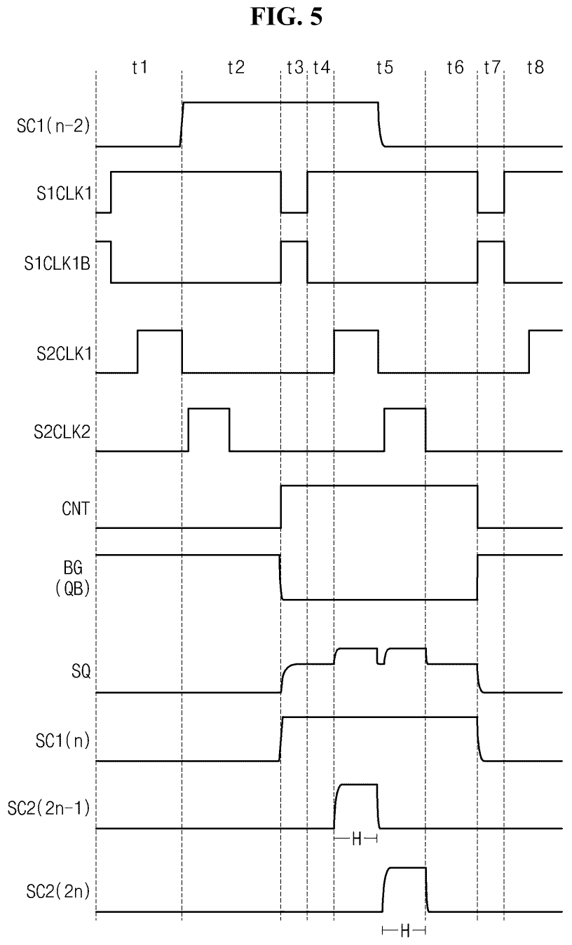

Hereinafter, the scan stage constituting the scan driving circuit of this embodiment can be described with further reference to FIG. 4. FIG. 4 is a view schematically illustrating a structure of a scan stage of a scan driving circuit according to an embodiment of the present disclosure. FIG. 5 is a waveform view schematically illustrating timings of signals driving a scan stage according to an embodiment of the present disclosure.

In FIG. 4, for convenience of explanation, the n-th scan stage SSC(n), which generates the first and second scan signals SC1 and SC2 that drive the 2n−1-th and 2n-th horizontal lines of the display region AA, among the scan stages SSC forming the scan driving circuit, is illustrated as an example. Meanwhile, the n+1-th scan stage SSC(n+1) arranged on the other side of the display region AA can be configured with substantially the same structure as the n-th scan stage SSC(n) arranged on one side of the display region AA.

Referring to FIGS. 4 and 5 along with FIGS. 1 to 3, the scan driving circuit can include a plurality of scan stages SSC that output the first and second scan signals SC1 and SC2 corresponding to a plurality of first and second scan lines SCL1 and SCL2 arranged in the display region AA.

As mentioned above, the plurality of scan stages SSC can be arranged to be distributed on both sides of the display region AA. For example, the odd scan stages SSC can be arranged sequentially along the vertical scan direction on one side of the display region AA, e.g., the left side, and sequentially driven, and the even scan stages SSC can be arranged sequentially along the vertical scan direction on the other side of the display region AA, e.g., the right side, and sequentially driven.

Each scan stage SSC can include, for example, a buffer portion that generates and outputs the scan signals SC1 and SC2, and a control portion that controls an output operation of the buffer portion.

The buffer portion of the scan stage SSC can include, for example, a first buffer portion BF1 that outputs the n-th first scan signal SC1(n) commonly applied to the 2n−1-th and 2n-th horizontal lines, which are odd and even horizontal lines, and a second-first buffer portion BF2_1 and a second-second buffer portion BF2_2 that output the 2n−1-th and 2n-th second scan signals SC2(2n−1) and SC2(2n) applied to the 2n−1-th and 2n-th horizontal lines, respectively.

The first buffer portion BF1 outputting the n-th first scan signal SC1(n) can include, for example, a first buffer transistor Tb1 which is a pull-up transistor, and a second buffer transistor Tb2 which is a pull-down transistor. Furthermore, the first buffer portion BF1 can include a first Q capacitor CQ1.

The second-first buffer portion BF2_1 outputting the 2n−1-th second scan signal SC2(2n−1) can include, for example, a third buffer transistor Tb3 which is a pull-up transistor, and a fourth buffer transistor Tb4 which is a pull-down transistor. Furthermore, the second-first buffer portion BF2_1 may include a second Q capacitor CQ2.

The second-second buffer portion BF2_2 outputting the 2n-th second scan signal SC2(2n) can include, for example, a fifth buffer transistor Tb5 that is a pull-up transistor, and a sixth buffer transistor Tb6 that is a pull-down transistor. In addition, the second-second buffer portion BF2_2 can include a third Q capacitor CQ3.

The control portion of the scan stage SSC can include, for example, a transfer transistor TA and a plurality of control transistors Ts1, Ts2, Ts3, and Ts4. The plurality of control transistors Ts1, Ts2, Ts3, and Ts4 can include, for example, first, second, third, and fourth control transistors Ts1, Ts2, Ts3, and Ts4.

Meanwhile, each of the transistors Tb1 to Tb6, Ts1 to Ts4, and TA constituting the scan stage SSC(n) can be a P-type transistor or an N-type transistor. Furthermore, each of the transistors Tb1 to Tb6, Ts1 to Ts4, and TA constituting the scan stage SSC(n) can be a transistor using an oxide semiconductor or a transistor using polycrystalline silicon.

In this embodiment, among the transistors Tb1 to Tb6, Ts1 to Ts4, and TA constituting the scan stage SSC(n), the second to sixth buffer transistors Tb2 to Tb6, the first and third control transistors Ts1 and Ts3, and the transfer transistor TA can be configured as N-type transistors including an oxide semiconductor layer, and the first buffer transistor Tb1 and the second and fourth control transistors Ts2 and Ts4 can be configured as P-type transistors including a polycrystalline silicon layer.

Here, the N-type transistors Tb2 to Tb6, Ts1, Ts3, and TA of the oxide semiconductor can be formed, for example, with the same structure as the N-type transistors DT, T1, T2, and T5 of the oxide semiconductor in the pixel P. The P-type transistors Tb1, Ts2, and Ts4 of polycrystalline silicon can be formed, for example, with the same structure as the P-type transistors T3 and T4 of polycrystalline silicon in the pixel P.

The first buffer transistor Tb1 of the first buffer portion BF1 can, for example, have a gate electrode that responds to a signal of a BG node to pull-up drive a first output terminal NO1 of the first buffer portion BF1. In addition, the second buffer transistor Tb2 can have a gate electrode that responds to a signal of the BG node to pull-down drive the first output terminal NO1.

In this regard, the first and second buffer transistors Tb1 and Tb2 of the first buffer portion BF1 can be configured with opposite P-type and N-type transistors, and their gate electrodes can be commonly connected to the BG node, so that their turn-on/turn-off states can be opposite. In this way, the first and second buffer transistors Tb1 and Tb2 can be configured as an inverter circuit, so that when one of them is turned on, the other can be turned off.

The P-type first buffer transistor Tb1 can have, for example, a first electrode (or source electrode) that receives a gate high voltage VGH output from the power supply portion 280, and a second electrode (or drain electrode) that is connected to the first output terminal NO1.

The N-type second buffer transistor Tb2 can have, for example, a second electrode (or drain electrode) that is connected to the first output terminal NO1, and a first electrode (or source electrode) that is provided with a gate low voltage VGL output from the power supply portion 280. In an example, a gate high voltage VGH is higher than a gate low voltage VGL.

The first control transistor Ts1 of the control portion can, for example, respond to the corresponding scan clock S1CLK1B to provide the n−2-th first scan signal SC1(n−2), which is an output signal of the n−2-th scan stage SSC that is a scan stage SSC arranged before the corresponding scan stage SSC(n), to a CNT node. The N-type first control transistor Ts1 can have, for example, a gate electrode to which the scan clock S1CLK1B is applied, a first electrode (or source electrode) connected to the CNT node, and a second electrode (or drain electrode) to which the first scan signal SC1(n−2) of the previous scan stage SSC is applied. Here, the scan clock S1CLK1B input to the first control transistor Ts1 can be referred to as a first B scan clock S1CLK1B.

The second control transistor Ts2 can be connected in parallel with the first control transistor Ts1 to form a transmission gate circuit. In this regard, the second control transistor Ts2 can, for example, provide the n−2-th first scan signal SC1(n−2), which is the output signal of the previous scan stage SSC, to the CNT node in response to the corresponding scan clock S1CLK1. The P-type second control transistor Ts2 can have, for example, a gate electrode to which the scan clock S1CLK1 is applied, a second electrode (or drain electrode) connected to the CNT node, and a first electrode (or source electrode) to which the previous first scan signal SC1(n−2) is applied. Here, the scan clock S1CLK1 input to the second control transistor Ts2 can be referred to as a first scan clock S1CLK1.

Here, the previous first scan signal SC1(n−2) applied to the first and second control transistors Ts1 and Ts2 can be used as a start signal (or carry signal). Meanwhile, when the scan stage SSC(n) is the scan stage of the first horizontal line, a start signal provided from the timing control portion 240 can be input to the first and second control transistors Ts1 and Ts2 to start the output operation of the scan stage.

In addition, the first scan clock S1CLK1 and the first B scan clock S1CLK1B can be clock signals having waveforms that are opposite in phase to each other.

The third control transistor Ts3 can transmit the gate low voltage VGL to the BG node in response to the voltage of the CNT node. The N-type third control transistor Ts3 can have, for example, a gate electrode connected to the CNT node, a second electrode (or drain electrode) connected to the BG node, and a first electrode (or source electrode) receiving the gate low voltage VGL.

The fourth control transistor Ts4 can be connected in series with the third control transistor Ts3 with the BG node interposed therebetween, and can transmit the gate high voltage VGH to the BG node in response to the voltage of the CNT node. The P-type fourth control transistor Ts4 can have, for example, a gate electrode connected to the CNT node, a second electrode (or drain electrode) connected to the BG node, and a first electrode (or source electrode) receiving the gate high voltage VGH.

As described above, the turn-on/turn-off states of the third and fourth control transistors Ts3 and Ts4 can be reversed.

The first Q capacitor CQ1 can be connected between the BG node and a voltage line that transmits the gate high voltage VGH. Here, a capacitance of the first Q capacitor CQ1 can be set to be greater than a capacitance of the storage capacitor Cst in the pixel P.

According to the configuration of the control portion and the first buffer portion BF1 as above, the first buffer portion BF1 can be controlled by the BG node, and the scan stage SSC(n) can shift the previous first scan signal SC1(n−2) according to the two scan clocks S1CLK1 and S1CLK1B input thereto and output the first scan signal SC1(n) to the corresponding first scan line SCL1.

As such, the n-th scan stage SSC(n) can receive the first scan clock S1CLK1 and the first B scan clock S1CLK1B, and generate and output the first scan signal SC1(n) from the first output terminal NO1 of the first buffer portion BF1.

Meanwhile, the transfer transistor TA of the control portion can be connected to, for example, the first output terminal NO1 and can transfer charges of the first output terminal NO1 to a SQ node in response to the gate high voltage VGH. The N-type transfer transistor TA can have, for example, a gate electrode to which the gate high voltage VGH is applied, a first electrode (or source electrode) connected to the SQ node, and a second electrode (or drain electrode) connected to the first output terminal NO1.

The second-first buffer portion BF2_1 and the second-second buffer portion BF2_2 can output, for example, two second scan signals SC2(2n−1) and SC2(2n) according to control of the SQ node and the BG node. Here, a signal of the BG node can have a phase substantially opposite to that of a signal of the SQ node, and a node of the second-first buffer portion BF2_1 and the second-second buffer portion BF2_2 connected to the BG node can be referred to as a QB node.

Regarding the second-first buffer portion BF2_1, the third buffer transistor Tb3 can, for example, have a gate electrode that responds to the signal of the SQ node to pull-up drive a second-first output terminal NO2_1 of the second-first buffer portion BF2_1. In addition, the fourth buffer transistor Tb4 can have a gate electrode that responses to a signal of the BG node, e.g., the QB node to pull-down drive the second-first output terminal NO2_1.

In this regard, the N-type third buffer transistor Tb3 can, for example, have a first electrode (or source electrode) that receives a corresponding scan clock S2CLK1, and a second electrode (or drain electrode) that is connected to the second-first output terminal NO2_1 of the scan stage SSC(n). Here, the scan clock S2CLK1 input to the third buffer transistor Tb3 can be referred to as a second-first scan clock S2CLK1.

The N-type fourth buffer transistor Tb4 can, for example, have a second electrode (or drain electrode) that is connected to the second-first output terminal NO2_1, and a first electrode (or source electrode) that is provided with the gate low voltage VGL.

The second Q capacitor CQ2 can be connected between the SQ node and the second-first output terminal NO2_1. Here, a capacitance of the second Q capacitor CQ2 can be set to be larger than the capacitance of the storage capacitor Cst in the pixel P.

The second-first buffer portion BF2_1 configured as above can have its output controlled by the BG node and the first output terminal NO1 of the first buffer portion BF1, and through this output control, the second-first scan clock S2CLK1 can be output as the second scan signal SC2(2n−1) to the second scan line SCL2 during the corresponding horizontal period (e.g., the horizontal period of the 2n−1-th horizontal line).

As such, in the n-th scan stage SSC(n), the second-first buffer portion BF2_1 can receive the second-first scan clock S2CLK1, and the BG node and the first output terminal NO1 of the first buffer portion BF1 can be used as output control nodes of the second-first buffer portion BF2_1, so that the 2n−1-th second scan signal SC2(2n−1) can be generated and output from the second-first output terminal NO2_1 of the second-first buffer portion BF2_1.

Regarding the second-second buffer portion BF2_2, the fifth buffer transistor Tb5 can, for example, have a gate electrode that responds to the signal of the SQ node to pull-up drive a second-second output terminal NO2_2 of the second-second buffer portion BF2_2. In addition, the sixth buffer transistor Tb6 can have a gate electrode that responses to a signal of the BG node, e.g., the QB node to pull-down drive the second-second output terminal NO2_2.

In this regard, the N-type fifth buffer transistor Tb5 can, for example, have a second electrode (or drain electrode) that receives a corresponding scan clock S2CLK2, and a first electrode (or source electrode) that is connected to the second-second output terminal NO2_2 of the scan stage SSC(n). Here, the scan clock S2CLK2 input to the fifth buffer transistor Tb5 can be referred to as a second-second scan clock S2CLK2. The second-second scan clock S2CLK2 can have a different phase from the second-first scan clock S2CLK1, and a clock pulse of the second-second scan clock S2CLK2 can be formed subsequent to a clock pulse of the second-first scan clock S2CLK1.

The N-type sixth buffer transistor Tb6 can have, for example, a second electrode (or drain electrode) connected to the second-second output terminal NO2_2, and a first electrode (or source electrode) provided with the gate low voltage VGL.

The third Q capacitor CQ3 can be connected between the SQ node and the second-second output terminal NO2_2. Here, a capacitance of the third Q capacitor CQ3 can be set to be larger than the capacitance of the storage capacitor Cst in the pixel P.

The second-second buffer portion BF2_2 configured as above can have its output controlled by the BG node and the first output terminal NO1 of the first buffer portion BF1, in the same manner as the second-first buffer portion BF2_1, and through this output control, the second-second scan clock S2CLK2 can be output as the second scan signal SC2(2n) to the second scan line SCL2 during the corresponding horizontal period (e.g., the horizontal period of the 2n-th horizontal line).

As such, in the n-th scan stage SSC(n), the second-second buffer portion BF2_2 can receive the second-second scan clock S2CLK2, and the BG node and the first output terminal NO1 of the first buffer portion BF1 can be used as output control nodes of the second-second buffer portion BF2_2, so that the 2n-th second scan signal SC2(2n) can be generated and output from the second-second output terminal NO2_2 of the second-second buffer portion BF2_2.

The output operations of the first scan signal SC1(n) and the second scan signals SC2(2n−1) and SC2(2n) in the n-th scan stage SSC(n) configured as above can be described with further reference to FIG. 5.

As mentioned above, the n-th scan stage SSC(n) can receive the corresponding four scan clocks, e.g., the first scan clock S1CLK1, the first B scan clock S1CLK1B, the second-first scan clock S2CLK1, and the second-second scan clock S2CLK2, and output one first scan signal SC1(n) and two second scan signals SC2(2n−1) and SC2(2n) that perform scanning operation of the corresponding two horizontal lines.

For example, during a first period t1, the previous first scan signal SC1(n−2) can be in a low state. Within the first period t1, the first scan clock S1CLK1 can transition from a low state to a high state, and conversely, the first B scan clock S1CLK1B can transition from a high state to a low state.

Here, during a section in which the first scan clock S1CLK1 is in a low state and the first B scan clock S1CLK1B is in a high state, the first and second control transistors Ts1 and Ts2 can be turned on, so that a low voltage (e.g., the gate low voltage VGL) of the previous first scan signal SC1(n−2) can be applied to the CNT node. Accordingly, the voltage at the CNT node can be at a low level.

Thereafter, during a section in which the first scan clock S1CLK1 is high and the first B scan clock S1CLK1B is low, the first and second control transistors Ts1 and Ts2 can be turned off, and the voltage at the CNT node can be maintained at a low level.

As such, in the first period t1, the voltage of the CNT node can be low. With the CNT node in a low state, the gate high voltage VGH can be applied to the BG node.

Furthermore, the QB node can become high, and the second buffer transistor Tb2, the fourth buffer transistor Tb4, and the sixth buffer transistor Tb6 can be turned on.

Furthermore, the gate low voltage VGL can be applied to the first output terminal NO1, and the SQ node can be in a low state.

In this way, in the first period t1, the BG node and the QB node can have a high state, and the SQ node can have a low state.

Accordingly, in the first buffer portion BF1, the first buffer transistor Tb1 can be turned off and the second buffer transistor Tb2 can be turned on, so that the gate low voltage VGL can be output from the first output terminal NO1, and the n-th first scan signal SC1(n) can have a low level.

In addition, in the second-first buffer portion BF2_1, the third buffer transistor Tb3 can be turned off and the fourth buffer transistor Tb4 can be turned on, so that the gate low voltage VGL can be output from the second-first output terminal NO2_1, and the 2n−1-th second scan signal SC2(2n−1) can have a low level.

In addition, in the second-second buffer portion BF2_2, the fifth buffer transistor Tb5 can be turned off and the sixth buffer transistor Tb6 can be turned on, so that the gate low voltage VGL can be output from the second-second output terminal NO2_2, and the 2n-th second scan signal SC2(2n) can have a low level.

Next, in a second period t2, the previous first scan signal SC1(n−2) can be switched to a high state. During the second period t2, the first scan clock S1CLK1 can be maintained in a high state and the first B scan clock S1CLK1B can be maintained in a low state. Accordingly, the first and second control transistors Ts1 and Ts2 can be maintained in a turn-off state, so that the voltage of the CNT node can be maintained at a low level.

Accordingly, similar to the first period t1, in the second period t2, the BG node and the QB node can be in a high state, and the SQ node can be in a low state.

Thus, the n-th first scan signal SC1(n) of the first buffer portion BF1 can maintain a low level, the 2n−1-th second scan signal SC2(2n−1) of the second-first buffer portion BF2_1 can maintain a low level, and the 2n-th second scan signal SC2(2n) of the second-second buffer portion BF2_2 can maintain a low level.

Next, in a third period t3, the previous first scan signal SC1(n−2) can maintain a high state. In addition, the first scan clock S1CLK1 can be switched to a low state, and conversely, the first B scan clock S1CLK1B can be switched to a high state.

In this case, the first and second control transistors Ts3 and Ts4 can be turned on, so that the high voltage (e.g., the gate high voltage VGH) of the previous first scan signal SC1(n−2) can be applied to the CNT node. Accordingly, the voltage of the CNT node can become high.

In this way, the CNT node can be in a high state, so that the gate low voltage VGL can be applied to the BG node.

In addition, the QB node can be in a low state, so that the second buffer transistor Tb2, the fourth buffer transistor Tb4, and the sixth buffer transistor Tb6 can be turned off.

In addition, the gate high voltage VGH can be applied to the first output terminal NO1, and the SQ node can have a high state.

In this way, in the third period t3, the BG node and the QB node can have a low state, and the SQ node can have a high state.

Accordingly, in the first buffer portion BF1, the first buffer transistor Tb1 can be turned on and the second buffer transistor Tb2 can be turned off, so that the gate high voltage VGH can be output from the first output terminal NO1, and the n-th first scan signal SC1(n) can have a high level.

In addition, in the second-first buffer portion BF2_1, the third buffer transistor Tb3 can be turned on and the fourth buffer transistor Tb4 can be turned off, so that the second-first scan clock S2CLK1 at a low level can be output from the second-first output terminal NO2_1, and the 2n−1-th second scan signal SC2(2n−1) can have a low level.

In addition, in the second-second buffer portion BF2_2, the fifth buffer transistor Tb5 can be turned on and the sixth buffer transistor Tb6 can be turned off, so that the second-second scan clock S2CLK2 at a low level can be output from the second-second output terminal NO2_2, and the 2n-th second scan signal SC2(2n) can have a low level.

Next, in the fourth period t4, the previous first scan signal SC1(n−2) can be maintained in a high state. In the fourth period t4, the first scan clock S1CLK1 can be switched to a high state and the first B scan clock S1CLK1B can be switched to a low state. Accordingly, the first and second control transistors Ts1 and Ts2 can be switched to a turn-off state, so that the voltage of the CNT node can be maintained at a high level.

Accordingly, similar to the third period t3, in the fourth period t4, the BG node and the QB node can be in a low state, and the SQ node can be in a high state.

Thus, the n-th first scan signal SC1(n) of the first buffer portion BF1 can maintain a high level, the 2n−1-th second scan signal SC2(2n−1) of the second-first buffer portion BF2_1 can maintain a low level, and the 2n-th second scan signal SC2(2n) of the second-second buffer portion BF2_2 can maintain a low level.

Next, in the fifth period t5, the previous first scan signal SC1(n−2) can maintain a high state for a certain section and then transition to a low state. In the fifth period t5, the first scan clock S1CLK1 can maintain a high state and the first B scan clock S1CLK1B can maintain a low state. Accordingly, the first and second control transistors Ts1 and Ts2 can be maintained in a turn-off state, and the voltage at the CNT node can be maintained at a high level.

Accordingly, similar to the fourth period t4, in the fifth period t5, the BG node and the QB node can be in a low state, and the SQ node can be in a high state.

Thus, the n-th first scan signal SC1(n) of the first buffer portion BF1 can maintain a high level.

Meanwhile, in the fifth period t5, the second-first scan clock S2CLK1 input to the second-first buffer portion BF2_1 can have a pulse of high voltage (e.g., gate high voltage VGH). Accordingly, the second-first buffer portion BF2_1 can output the 2n−1-th second scan signal SC2(2n−1) of the high pulse during the horizontal period H of the 2n−1-th horizontal line.

In addition, in the fifth period t5, the second-second scan clock S2CLK2 input to the second-second buffer portion BF2_2 can have a pulse of a high voltage (e.g., gate high voltage VGH). Accordingly, the second-second buffer portion BF2_2 can output the 2n-th second scan signal SC2(2n) of the high pulse during the horizontal period H of the 2n-th horizontal line.

As such, while the second scan signals SC2(2n−1) and SC2(2n) of the gate high voltage VGH are output from the second-first and second-second output terminals NO2_1 and NO2_2, the SQ node can be bootstrapped by the second Q capacitor CQ2 and the third Q capacitor CQ3, so that the voltage of the SQ node can be substantially increased to a voltage higher than the gate high voltage VGH. Due to the voltage increase of the SQ node by the bootstrapping action, the second-first scan clock S2CLK1 and the second-second scan clock S2CLK2 can be stably output from the second-first output terminal NO2_1 and the second-second output terminal NO2_2.

Meanwhile, in the fifth period t5, when the second-first scan clock S2CLK1 transitions to a low voltage, the voltage of the second-first output terminal NO2_1 can transition to a low voltage, allowing the second scan signal SC2(2n−1) of a low level to be output. Similarly, when the second-second scan clock S2CLK2 transitions to a low voltage, the voltage of the second-second output terminal NO2_2 can transition to a low voltage, allowing the second scan signal SC2(2n) of a low level to be output.

In addition, when the second-first and second-second scan clocks S2CLK1 and S2CLK2 transition to a low state as described above, the voltage of the SQ node can be substantially lowered to the gate high voltage VGH by the second Q capacitor CQ2 and the third Q capacitor CQ3.

Next, in a sixth period t6, the first scan signal SC1(n−2) can be maintained in a low state. In addition, the first scan clock S1CLK1 can be maintained in a high state, and the first B scan clock S1CLK1B can be maintained in a low state. Accordingly, the first and second control transistors Ts1 and Ts2 can be maintained in a turn-off state, and the voltage of the CNT node can be maintained at a high level.

Accordingly, similar to the fifth period t5, in the sixth period t6, the BG node and the QB node can be in a low state, and the SQ node can be in a high state.

Thus, the n-th first scan signal SC1(n) of the first buffer portion BF1 can be maintained at a high level.

Meanwhile, in the sixth period t6, the second-first scan clock S2CLK1 input to the second-first buffer portion BF2_1 can have a low voltage (e.g., gate low voltage VGL). Accordingly, the second-first buffer portion BF2_1 can output the 2n−1-th second scan signal SC2(2n−1) of a low level.

In addition, in the sixth period t6, the second-second scan clock S2CLK2 input to the second-second buffer portion BF2_2 can have a low voltage (e.g., gate low voltage VGL). Accordingly, the second-second buffer portion BF2_2 can output the 2n-th second scan signal SC2(2n) of a low level.

Next, in a seventh period t7, the previous first scan signal SC1(n−2) can maintain a low state. In addition, the first scan clock SCLK1 can be switched to a low state, and conversely, the first B scan clock SCLKB1 can be switched to a high state. Accordingly, the first and second control transistors Ts1 and Ts2 can be turned on, and the voltage of the CNT node can be at a low level.

Accordingly, in the seventh period t7, the BG node and the QB node can be in a high state, and the SQ node can be in a low state.

Thus, in the first buffer portion BF1, the gate low voltage VGL can be output from the first output terminal NO1, and the n-th first scan signal SC1(n) can have a low level.

Furthermore, in the second-first buffer portion BF2_1, the gate low voltage VGL can be output from the second-first output terminal NO2_1, and the 2n−1-th second scan signal SC2(2n−1) can have a low level.

Furthermore, in the second-second buffer portion BF2_2, the gate low voltage VGL can be output from the second-second output terminal NO2_2, and the 2n-th second scan signal SC2(2n) can have a low level.

Next, in an eighth period t8, the previous first scan signal SC1(n−2) can be maintained in a low state. In addition, the first scan clock S1CLK1 can be switched to a high state and the first B scan clock S1CLK1B can be switched to a low state. Accordingly, the first and second control transistors Ts1 and Ts2 can be turned off, and the voltage of the CNT node can be maintained at a low level.

Accordingly, similar to the seventh period t7, in the eighth period t8, the BG node and the QB node can have a high state and the SQ node can have a low state.

Thus, the n-th first scan signal SC1(n) of the first buffer portion BF1 can be maintained at a low level, the 2n−1-th second scan signal SC2(2n−1) of the second-first buffer portion BF2_1 can be maintained at a low level, and the 2n-th second scan signal SC2(2n) of the second-second buffer portion BF2_2 can be maintained at a low level.

Through the above operations, the scan stage SSC(n) can generate and output the first scan signal SC1(n) and the second scan signals SC2(2n−1) and SC2(2n). The first scan signal SC1(n) and the second scan signals SC2(2n−1) and SC2(2n) can be applied to the corresponding two horizontal lines, e.g., the 2n−1-th and 2n-th horizontal lines and perform scanning operation of them.

Meanwhile, the n+1-th scan stage SSC(n+1), which is positioned opposite to the n-th scan stage SSC(n) with the display region AA located therebetween, can operate similarly to the n-th scan stage (SSC(n)). For example, the n+1-th scan stage SSC(n+1) can receive the n−1-th first scan signal SC1(n−1), which is the previous first scan signal, and generate and output the n+1-th first scan signal SC1(n+1) and the 2n+1-th and 2n+2-th second scan signals SC2(2n+1) and SC2(2n+2). The first scan signal SC1(n+1) and the second scan signals SC2(2n+1) and SC2(2n+2) can be applied to the corresponding two horizontal lines, e.g., the 2n+1-th and 2n+2-th horizontal lines and perform scanning operation of them.

As described above, in this embodiment, the scan stages SSC can be provided on both sides of the display region (AA) in a unit of four horizontal lines, and in each scan stage SSC, the first buffer portion BF1 that outputs the first scan signal SC1 and the second-first, and second-second buffer portions BF2_1 and BF2_2 that output the two second scan signals SC2 can share control nodes. By sharing the control nodes, each scan stage SSC can output the first scan signal SC1 that commonly drives the corresponding two horizontal lines, and the two second scan signals SC2 that individually drive the corresponding two horizontal lines.

Accordingly, the vertical length of the scan stage SSC can become larger than the widths of the buffer transistors Tb1 to Tb6, so that the buffer transistors Tb1 to Tb6 constituting the scan stage SSC can be arranged in the vertical direction, thereby narrowing the width of the non-display region NA.

Therefore, the bezel width of the light emitting display apparatus 10 can be reduced, enabling a narrow bezel.

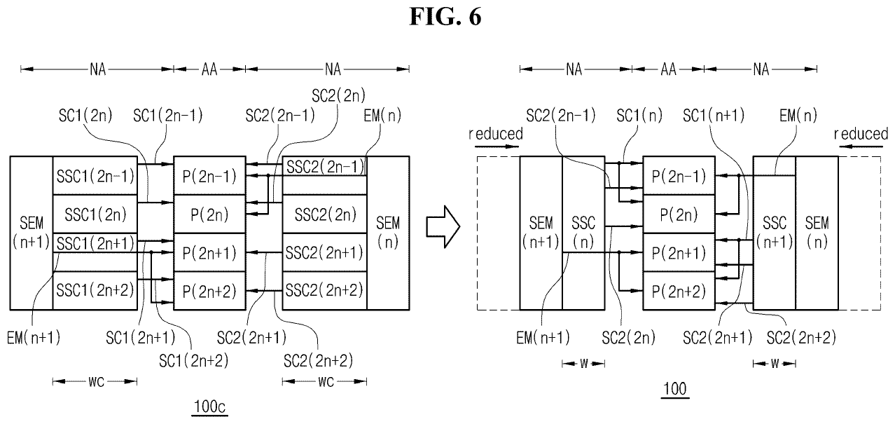

This can be described with further reference to FIG. 6. FIG. 6 is a view comparing non-display regions of display panels according to a comparative example and an embodiment of the present disclosure.

Referring to FIG. 6, in the display panel 100c of the comparative example, first scan stages SSC1 that output first scan signals (SC1: SC1(2n−1) to SC1(2n+2)) are arranged in a unit of one horizontal line on the left side of the display region AA which is one side of the display region AA, and second scan stages SSC2 that outputs second scan signals (SC2: SC2(2n−1) to SC2(2n+2)) are arranged in a unit of one horizontal line on the right side of the display region AA which is the other side of the display region AA.

As such, in the comparative example, the first and second scan stages SSC1 and SSC2 are provided on both sides of the display region AA in a unit of one horizontal line. In this case, since the vertical length of each of the first and second scan stages SSC1 and SSC2 is smaller than the widths of the buffer transistors in the scan stage, the buffer transistors need to be arranged in the horizontal direction, which increases the width of the non-display region (NA). For example, the first and second scan stages SSC1, SSC2 of the comparative example each have a width wc of approximately 200 um, so that the width of the non-display region NA is wide.

However, in this embodiment, the scan stages SSC can be provided on both sides of the display region AA in a unit of four horizontal lines, and each scan stage SSC can output the first scan signal (SC1: SC1(n) or SC(n+1)) and the second scan signals (SC2: SC2(2n−1) and SC(2n) or SC(2n+1) and SC2(2n+2)) that drive the corresponding two horizontal lines.

Accordingly, the vertical length of the scan stage SSC can become larger than the widths of the buffer transistors, so that the buffer transistors constituting the scan stage SSC can be arranged in the vertical direction, and thus the width w of the scan stage SSC can be reduced. For example, the scan stage SSC of this embodiment can have the width w of approximately 90 um.

Therefore, the width of the non-display region NA of this embodiment can be reduced, so that the light emitting display apparatus 10 can effectively implement a narrow bezel.

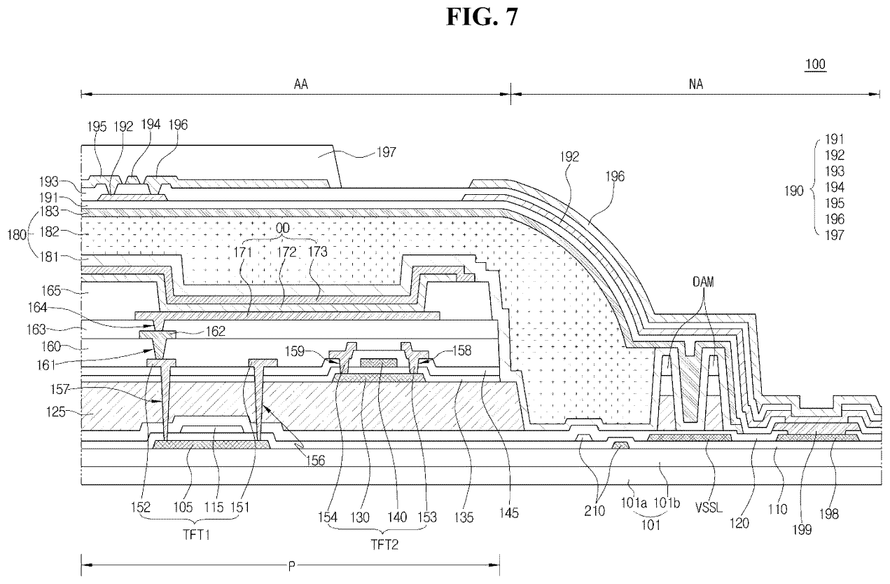

Hereinafter, an example of a cross-sectional structure of the display panel 100 of this embodiment is described with further reference to FIG. 7. FIG. 7 is a cross-sectional view schematically illustrating an example of a cross-sectional structure of a display panel according to an embodiment of the present disclosure.

In FIG. 7, for convenience of explanation, two thin film transistors TFT1 and TFT2 are illustrated in the pixel P within the display region AA. Here, the thin film transistor TFT1 positioned relatively lower and closer to the substrate 101 is referred to as a first thin film transistor TFT1, which can be a polycrystalline silicon thin film transistor. The thin film transistor TFT2 positioned relatively upper and farther from the substrate 101 is referred to as a second thin film transistor TFT2, which can be an oxide thin film transistor.

Meanwhile, the first thin film transistor TFT1 can be a third transistor (T3 of FIG. 2), but not limited thereto. In addition, the second thin film transistor TFT2 can be a driving transistor (DT of FIG. 2), but not limited thereto.

The substrate 101 can be configured as, for example, a thin glass substrate (or glass film) or a plastic substrate (or plastic film) so as to implement flexible characteristics of the display panel 100.

Here, in a case where the substrate 101 is configured as a glass substrate, for example, the substrate 101 can have a thickness of approximately 0.2 mm.

Meanwhile, in a case where the substrate 101 is configured as a plastic substrate, for example, the substrate 101 can include at least one polyimide layer. In this embodiment, the substrate 101 configured of two polyimide layers, which are a first polyimide layer 101a and a second polyimide layer 101b, is taken as an example. In this case, the substrate can include an inorganic insulating layer between the first polyimide layer 101a and a second polyimide layer 101b.

The first thin film transistor TFT1 can include a first semiconductor layer 105 disposed on the substrate 101, a first gate electrode 115 overlapping the first semiconductor layer 105 with a first insulating layer 110 interposed therebetween, and a first source electrode 151 and a first drain electrode 152 located on a fourth insulating layer 145 over the first gate electrode 115. Here, the first semiconductor layer 105 can be formed of polycrystalline silicon, but not limited thereto.

The first semiconductor layer 105 can include a central channel region and source and drain regions on both sides thereof. The first source electrode 151 and the first drain electrode 152 can be connected to the source region and the drain region of the first semiconductor layer 105 through the first and second contact holes 156 and 157 that are formed in the insulating layers 110, 120, 125, 135, and 145 located below the first source electrode 151 and the first drain electrode 152.

A second insulating layer 120 can be formed on the first gate electrode 115 of the first thin film transistor TFT1.

A first interlayered insulating layer 125 can be formed on the second insulating layer 120. The second thin film transistor TFT2 can be formed on the first interlayered insulating layer 125.

The second thin film transistor TFT2 can include a second semiconductor layer 130 on the first interlayered insulating layer 125, a second gate electrode 140 overlapping the second semiconductor layer 130 with a third insulating layer 135 interposed therebetween, and a second source electrode 153 and a second drain electrode 154 located on the fourth insulating layer 145 over the second gate electrode 140. Here, the second semiconductor layer 130 can be formed of an oxide semiconductor, but not limited thereto.

The second semiconductor layer 130 can include a central channel region and source and drain regions on both sides thereof. The second source electrode 153 and the second drain electrode 154 can be connected to the source and drain regions of the second semiconductor layer 130 through third and fourth contact holes 158 and 159 formed in the insulating layers 135 and 145 located below the second source electrode 153 and the second drain electrode 154.

A second interlayered insulating layer (or first planarization layer) 160 can be formed on the second thin film transistor TFT2.

Here, the first, second, third, and fourth insulating layers 110, 120, 135, and 145 can be formed of an inorganic insulating material such as silicon nitride or silicon oxide, but not limited thereto.

In addition, the first and second interlayered insulating layers 125 and 160 can be formed of an organic insulating material such as photo acrylic or benzocyclobutene, but not limited thereto.

A connection electrode 162 can be formed on the second interlayered insulating layer 160. The connection electrode 162 can be connected to the first drain electrode 152 through a contact hole 161 formed in the second interlayered insulating layer 160.

A third interlayered insulating layer (or second planarization layer) 163 can be formed on the connection electrode 162. The third interlayered insulating layer 163 can be formed of an organic insulating material such as photo acrylic or benzocyclobutene, but not limited thereto.

The light emitting diode OD and a bank 165 can be formed on the third interlayered insulating layer 163.

The light emitting diode OD can include an anode electrode (or first electrode) 171, a light emitting layer 172, and a cathode electrode (or second electrode) 173.

The anode electrode 171 can be connected to the connection electrode 162 through the contact hole 164 formed in the third interlayered insulating layer 163.

The bank 165 can be disposed along a boundary of the pixel P and can be formed to cover an edge of the anode electrode 171. The light emitting layer 172 can be formed on the anode electrode 171 exposed through an opening of the bank 165.

The cathode electrode 173 can be formed on the light emitting layer 172 and can be applied with the low-potential driving voltage (EVSS of FIG. 2).

An encapsulation layer 180 can be formed on the cathode electrode 173. The encapsulation layer 180 can include at least one inorganic encapsulation layer and at least one organic encapsulation layer, but not limited thereto. In this disclosure, a structure of the encapsulation layer 180, in which a first encapsulation layer 181, a second encapsulation layer 182, and a third encapsulation layer 183 are sequentially stacked, is described as an example.

The first encapsulation layer 181 can be formed on the substrate 101 on which the cathode electrode 173 is formed. The third encapsulation layer 183 can be formed on the substrate 101 on which the second encapsulation layer 182 is formed, and can be formed to surround an upper surface, a lower surface, and a side surface of the second encapsulation layer 182 together with the first encapsulation layer 181. The first encapsulation layer 181 and the third encapsulation layer 183 can minimize or prevent external moisture or oxygen from penetrating into the light emitting diode OD. The first encapsulation layer 181 and the third encapsulation layer 183 can be formed of an inorganic insulating material capable of low-temperature deposition, such as silicon nitride, silicon oxide, silicon oxynitride, or aluminum oxide.

The second encapsulation layer 182 can acts as a buffer to relieve stress between layers due to bending of the light emitting display apparatus 10, and can flatten steps between layers. The second encapsulation layer 182 can be formed on the substrate 101 on which the first encapsulation layer 181 is formed, using a non-photosensitive organic insulating material such as acrylic resin, epoxy resin, phenolic resin, polyamide resin, polyimide resin, polyethylene, or silicon oxycarbon (SiOC), or a photosensitive organic insulating material such as photo acrylic, but not limited thereto. When the second encapsulation layer 182 is formed through an inkjet method, a dam DAM can be placed in the non-display region NA to prevent the second encapsulation layer 182 in liquid form from spreading to an edge of the substrate 101. The dam DAM can be disposed closer to the edge of the substrate 101 than the second encapsulation layer 182. By the dam DAM, the second encapsulation layer 182 can be prevented from spreading to a pad region, where a conductive pad is disposed, on an outermost edge of the substrate 101.

The dam DAM can be designed to prevent the spreading of the second encapsulation layer 182, but if the second encapsulation layer 182 is formed to exceed a height of the dam DAM during a process, the second encapsulation layer 182 as an organic layer can be exposed to an outside, so that moisture, etc. can easily penetrate into the light emitting element. To prevent this, 10 or more dam DAM can be formed in succession, but not limited thereto.

The dam DAM can be formed simultaneously with the first interlayered insulating layer 125, the second interlayered insulating layer 160, and the third interlayered insulating layer 163. When forming the first interlayered insulating layer 125, a lower layer of the dam DAM can be formed together, and when forming the second and third interlayered insulating layers 160 and 163, an upper layer of the dam DAM can be formed together, so that the dam DAM can be formed in a triple laminated structure. As another example, the dam DAM can be formed with one or two of the first, second, and third interlayered insulating layers 125, 160, and 163.

Accordingly, the dam DAM can be formed of the same material as the first interlayered insulating layer 125, the second interlayered insulating layer 160, and the third interlayered insulating layer 163, but not limited thereto.

The dam DAM can be formed to overlap a low-potential driving voltage line VSSL. For example, the low-potential driving voltage line VSSL can be formed at a lower layer of a region, where the dam DAM is located, in the non-display region NA.

The low-potential driving voltage line VSSL and the gate driving portion 210 configured in the GIP structure can be formed along a periphery of the display panel 100, and the low-potential driving voltage line VSSL can be located outside the gate driving portion 210. In addition, the low-potential driving voltage line VSSL can be connected to the cathode electrode 173 to apply the low-potential driving voltage EVSS. The gate driving portion 210 is simply shown in a planar and cross-sectional manner in the drawings, but can be configured with the same structure as the first thin film transistor TFT1 and/or the second thin film transistor TFT2 of the display region AA.

A touch layer (or touch element layer) 190 can be disposed on the encapsulation layer 180. In the touch layer 190, a touch buffer layer 191 can be positioned between a touch sensor metal including touch electrode connection lines 192 and 194 and touch electrodes 195 and 196, and the cathode electrode 173 of the light emitting diode OD.

The touch buffer layer 191 can block a chemical solution (developer, etchant, etc.) used in a manufacturing process of the touch sensor metal disposed on the touch buffer layer 191 or moisture from the outside from penetrating into the light emitting layer 172 containing an organic material. Accordingly, the touch buffer layer 191 can prevent damage to the light emitting layer 172 that is vulnerable to the chemical solution or moisture.

According to a mutual-capacitance-based touch sensor structure, the touch electrodes 195 and 196 can be disposed on the touch buffer layer 191, and the touch electrodes 195 and 196 can be arranged to cross each other.

The touch electrode connection lines 192 and 194 can electrically connect the touch electrodes 195 and 196. One of the touch electrode connection lines 192 and 194, and the touch electrodes 195 and 196 can be located at different layers with a touch insulation layer 193 interposed therebetween. In addition, one of the touch electrode connection lines 192 and 194 and the other of the touch electrode connection lines 192 and 194 can be located at different layers with the touch insulation layer 193 interposed therebetween.

The touch electrode connection lines 192 and 194 can be arranged to overlap the bank 165, thereby preventing decrease in aperture ratio, but not limited thereto.

Meanwhile, a part of the touch electrodes 195 and 196 and a part of the touch electrode connection line 192 can extend along the top and side surfaces of the encapsulation layer 180 and the top and side surfaces of the dam DAM and be electrically connected to a touch driving circuit through a touch pad 198 and 199.

A part of the touch electrodes 195 and 196 and a part of the touch electrode connection line 192 can receive a touch driving signal from the touch driving circuit and transmit it to the touch electrodes 195 and 196, and can transmit a touch sensing signal detected by the touch electrodes 195 and 196 to the touch driving circuit.

In this regard, for example, a driving IC (e.g., data IC, etc.) of the data driving portion 220 including the touch driving circuit can be configured in a COF type and connected to the non-display region NA of the substrate 101 of the display panel 100, and in this case, an end of the touch pad 198 and 199 can be connected to a flexible circuit film on which the driving IC is mounted, so that a signal can be transmitted.

A touch protective layer 197 can be disposed on the touch electrodes 195 and 196. In the drawing, the touch protective layer 197 is shown as being disposed only on the touch electrodes 195 and 196, but not limited thereto, and the touch protective layer 197 can extend before or after the dam DAM to be disposed on the touch electrode connection line 192.

In addition, a color filter can be disposed on the encapsulation layer 180. The color filter can be positioned on the touch layer 190, or between the encapsulation layer 180 and the touch layer 190.

Various examples and aspects of the present disclosure are described below. These are provided as examples, and do not limit the scope of the present disclosure.

In one or more aspects of the present disclosure, a light emitting display apparatus includes: a display region and a non-display region; and a scan driving circuit located in the non-display region and including a scan stage which includes a first buffer portion configured to output a first scan signal, and a second-first buffer portion and a second-second buffer portion configured to output second scan signals, wherein the first buffer portion, the second-first buffer portion, and the second-second buffer portion share control nodes to commonly drive corresponding horizontal lines using the first scan signal and to individually drive the corresponding horizontal lines using the second scan signals, respectively.

One of the second scan signals may drive one of the corresponding horizontal lines, and another one of the second scan signals may drive another one of the corresponding horizontal lines.

The control nodes may include an input node and an output node of the first buffer portion.

The input node may be connected to gate electrodes of transistors of the first buffer portion.

The input node may be connected to a gate electrode of a transistor of the second-first buffer and to a gate electrode of a transistor of the second-second buffer portion.

The output node may be connectable to a gate electrode of another transistor of the second-first buffer and to a gate electrode of another transistor of the second-second buffer portion.

The output node is configured to output the first scan signal.

The transistors of the first buffer portion, the transistor and the another transistor of the second-first buffer, and the transistor and the another transistor of the second-second buffer may be arranged in a vertical direction, which is perpendicular to a direction of the corresponding horizontal lines.

As described above, in the embodiment of the present disclosure, the scan stages can be provided on both sides of the display region in a unit of four horizontal lines, and in each scan stage, the first buffer portion outputting the first scan signal and the second-first and second-second buffer portions outputting the two second scan signals can share the control nodes, so that each scan stage can output the first scan signal and the two second scan signals driving the two horizontal lines.

Accordingly, the vertical length of the scan stage can become larger than the widths of the buffer transistors, so that the buffer transistors constituting the scan stage can be arranged vertically, thereby reducing the width of the scan stage.

Therefore, the width of the non-display region of the light emitting display apparatus can be reduced, so that the light emitting display apparatus can effectively implement a narrow bezel.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide non-limiting examples of the technical features of the present disclosure for illustrative purposes. In other words, the disclosed embodiments illustrate the scope of the technical features of the present disclosure and are not intended to be limiting in any respect. Thus, the scope of the present disclosure is not limited to the embodiments shown, but is to be accorded the widest scope consistent with the claims and their equivalents.

What is claimed is:

1. A light emitting display apparatus, comprising:
a display panel including a display region and a non-display region, the display region including pixels;
a light emitting diode and a plurality of transistors electrically connected to the light emitting diode, in a pixel; and
a scan driving circuit located in the non-display region and including a scan stage which includes a first buffer portion that is configured to output a first scan signal commonly applied to the pixels of two adjacent horizontal lines, and a second-first buffer portion and a second-second buffer portion that are configured to output two second scan signals applied to the pixels of the two adjacent horizontal lines, respectively,
wherein the first buffer portion includes a first buffer transistor and a second buffer transistor, wherein a gate electrode of the first buffer transistor and a gate electrode of the second buffer transistor are commonly connected to a BG node,
wherein the second-first buffer portion includes a third buffer transistor and a fourth buffer transistor, wherein a gate electrode of the third buffer transistor is connected to an SQ node for receiving a voltage of an output terminal of the first buffer portion, wherein a gate electrode of the fourth buffer transistor is connected to the BG node,
wherein the second-second buffer portion includes a fifth buffer transistor and a sixth buffer transistor, wherein a gate electrode of the fifth buffer transistor is connected to the SQ node, wherein a gate electrode of the sixth buffer transistor is connected to the BG node,
wherein the first buffer transistor is configured to receive a gate high voltage,
wherein each of the second, fourth, and sixth buffer transistors is configured to receive a gate low voltage, and
wherein the third and fifth buffer transistors are configured to receive a second-first scan clock and a second-second scan clock, respectively.

2. The light emitting display apparatus of claim 1, wherein the scan stage includes:
a first control transistor and a second control transistor which are connected in parallel with each other, are configured to receive a carry signal, and are connected to a CNT node; and
a third control transistor and a fourth control transistor which are connected in series with each other with the BG node interposed therebetween, and have gate electrodes connected to the CNT node.

3. The light emitting display apparatus of claim 2, wherein the scan stage includes a transfer transistor connected between the output terminal of the first buffer portion and the SQ node.

4. The light emitting display apparatus of claim 2, wherein the carry signal is a first scan signal of a previous scan stage.

5. The light emitting display apparatus of claim 2, wherein the first control transistor is configured as an N-type transistor, and has a gate electrode for receiving a first B scan clock,
wherein the second control transistor is configured as a P-type transistor and has a gate electrode for receiving a first scan clock, and
wherein the first scan clock and the first B scan clock have opposite phases.

6. The light emitting display apparatus of claim 2, wherein the third control transistor is configured as an N-type transistor, and has a source electrode for receiving the gate low voltage, and
wherein the fourth control transistor is configured as a P-type transistor, and has a source electrode for receiving the gate high voltage.

7. The light emitting display apparatus of claim 3, wherein the transfer transistor has a gate electrode for receiving the gate high voltage.

8. The light emitting display apparatus of claim 1, wherein the scan driving circuit includes n-th and n+1-th scan stages which correspond to 2n−1-th to 2n+2-th horizontal lines of the display region, and are respectively disposed on one side and the other side of the display region,
wherein the n-th scan stage is configured to output an n-th first scan signal and 2n−1-th and 2n-th second scan signals for driving the 2n−1-th and 2n-th horizontal lines,
wherein the n+1-th scan stage is configured to output an n+1-th first scan signal and 2n+1-th and 2n+2-th second scan signals for driving the 2n+1-th and 2n+2-th horizontal lines, and
wherein n is a whole number.

9. The light emitting display apparatus of claim 1, wherein a width direction of the first, second, third, fourth, fifth, and sixth buffer transistors of the scan stage is vertical.

10. The light emitting display apparatus of claim 8, further comprising an n-th emission stage disposed on the other side of the display region, and an n+1-th emission stage disposed on the one side of the display region,
wherein the n-th emission stage is configured to output an n-th emission control signal for driving the 2n−1-th and 2n-th horizontal lines, and
wherein the n+1-th emission stage is configured to output an n+1-th emission control signal for driving the 2n+1-th and 2n+2-th horizontal lines.

11. The light emitting display apparatus of claim 1, wherein the pixel includes:
a driving transistor;
a first transistor connected between a gate electrode and a drain electrode of the driving transistor, and configured to receive the first scan signal; and
a second transistor connected between a source electrode of the driving transistor and a data line, and configured to receive one of the two second scan signals.

12. A light emitting display apparatus, comprising:
a display panel including a display region and a non-display region, the display region including pixels;
a light emitting diode and a plurality of transistors electrically connected to the light emitting diode, in a pixel; and
a plurality of scan stages in the non-display region, each of the plurality of scan stages including a first buffer portion that is configured to output a first scan signal commonly applied to the pixels of two adjacent horizontal lines, and a second-first buffer portion and a second-second buffer portion that are configured to output two second scan signals applied to the pixels of the two adjacent horizontal lines, respectively,
wherein the plurality of scan stages include n-th and n+1-th scan stages which correspond to 2n−1-th to 2n+2-th horizontal lines of the display region, and are respectively disposed on one side and the other side of the display region,
wherein the n-th scan stage is configured to output an n-th first scan signal and 2n−1-th and 2n-th second scan signals for driving the 2n−1-th and 2n-th horizontal lines, and
wherein the n+1-th scan stage is configured to output an n+1-th first scan signal and 2n+1-th and 2n+2-th second scan signals for driving the 2n+1-th and 2n+2-th horizontal lines.

13. The light emitting display apparatus of claim 12, wherein the first buffer portion includes a first buffer transistor and a second buffer transistor, wherein a gate electrode of the first buffer transistor and a gate electrode of the second buffer transistor are commonly connected to a BG node,
wherein the second-first buffer portion includes a third buffer transistor and a fourth buffer transistor, wherein a gate electrode of the third buffer transistor is connected to an SQ node for receiving a voltage of an output terminal of the first buffer portion, wherein a gate electrode of the fourth buffer transistor is connected to the BG node,
wherein the second-second buffer portion includes a fifth buffer transistor and a sixth buffer transistor, wherein a gate electrode of the fifth buffer transistor is connected to the SQ node, wherein a gate electrode of the sixth buffer transistor is connected to the BG node,
wherein the first buffer transistor is configured to receive a gate high voltage,
wherein each of the second, fourth, and sixth buffer transistors is configured to receive a gate low voltage, and
wherein the third and fifth buffer transistors are configured to receive a second-first scan clock and a second-second scan clock, respectively.

14. The light emitting display apparatus of claim 13, wherein each of the plurality of scan stages includes:
a first control transistor and a second control transistor which are connected in parallel with each other, are configured to receive a carry signal, and are connected to a CNT node; and
a third control transistor and a fourth control transistor which are connected in series with each other with the BG node interposed therebetween, and have gate electrodes connected to the CNT node.

15. The light emitting display apparatus of claim 14, wherein each of the plurality of scan stages includes a transfer transistor connected between the output terminal of the first buffer portion and the SQ node.

16. The light emitting display apparatus of claim 14, wherein the n-th scan stage is configured to receive a first scan signal of an n-2-th scan stage, which is disposed on the one side of the display region, as the carry signal, and
wherein the n+1-th scan stage is configured to receive a first scan signal of an n-1-th scan stage, which is disposed on the other side of the display region, as the carry signal.

17. The light emitting display apparatus of claim 13, wherein a width direction of the first, second, third, fourth, fifth, and sixth buffer transistors of each of the plurality of scan stages is vertical.

18. The light emitting display apparatus of claim 12, further comprising an n-th emission stage disposed on the other side of the display region, and an n+1-th emission stage disposed on the one side of the display region,
wherein the n-th emission stage is configured to output an n-th emission control signal for driving the 2n−1-th and 2n-th horizontal lines, and
wherein the n+1-th emission stage is configured to output an n+1-th emission control signal for driving the 2n+1-th and 2n+2-th horizontal lines.

19. The light emitting display apparatus of claim 12, wherein the pixel includes:
a driving transistor;
a first transistor connected between a gate electrode and a drain electrode of the driving transistor, and configured to receive the first scan signal; and
a second transistor connected between a source electrode of the driving transistor and a data line, and configured to receive one of the two second scan signals.
